(19) United States
(12) Patent Application Publication
(10) Pub. No.: US 2026/0020154 A1
(43) Pub. Date: Jan. 15, 2026

(54) WIRE HARNESS

(71) Applicant: YAZAKI CORPORATION, Tokyo (JP)

(72) Inventors: Tatsuya Oga, Makinohara-shi (JP); Kota Morishige, Makinohara-shi (JP)

(21) Appl. No.: 19/263,508

(22) Filed: Jul. 9, 2025

(30) Foreign Application Priority Data
Jul. 11, 2024 (JP) 2024-111431

(51) Int. Cl. H05K 1/11; H01R 12/59; H01R 12/77; H05K 1/02

(52) U.S. Cl. CPC H05K 1/118; H01R 12/592; H01R 12/777; H05K 1/028; H05K 2201/10272

(57) ABSTRACT

A wire harness includes a flexible printed circuit board and a connector. The flexible printed circuit board includes a first region, a second region, and an intermediate region. Each of the plurality of circuit patterns includes a first contact portion, a second contact portion, and a conductive path. The intermediate region of the flexible printed circuit board is bent at a bent portion such that a direction of a first extending portion intersects a direction of a second extending portion. An arrangement order of the plurality of conductive paths in the first extending portion and an arrangement order of the plurality of conductive paths in the second extending portion are the same in a rotation direction when the bent portion is viewed in plan view.

### CROSS-REFERENCE TO RELATED APPLICATION(S)

The present application claims priority to and incorporates by reference the entire contents of Japanese Patent Application No. 2024-111431 filed in Japan on Jul. 11, 2024.

### BACKGROUND OF THE INVENTION

### 1. Field of the Invention

The present invention relates to a wire harness.

### 2. Description of the Related Art

Conventionally, there is a flexible printed circuit board (FPC). JP 2014-099 537 A discloses a technique that enables branched wires to cross each other by making an FPC double-sided.

For a wire harness including a flexible printed circuit board and a connector, a request for switching the arrangement order of circuit patterns in order to support a device to which the connector is connected may be provided. Examples of the reason for such a request to switch the arrangement order include matching the arrangement order of terminals of a mating connector. It is conceivable to form the flexible printed circuit board into multiple layers in order to switch the arrangement order of the circuit patterns, but in this case, manufacturing cost increases.

### SUMMARY OF THE INVENTION

An object of the present invention is to provide a wire harness in which the arrangement order of circuit patterns can be switched while an increase in cost is suppressed.

In order to achieve the above mentioned object, a wire harness according to one aspect of the present invention includes a flexible printed circuit board having a plurality of circuit patterns in a single conductive layer and routed in a device; and a connector having a plurality of terminals connected to the plurality of circuit patterns, wherein the flexible printed circuit board includes a first region connected to an object, a second region connected to the connector, and an intermediate region extending between the first region and the second region, each of the plurality of circuit patterns includes a first contact portion disposed in the first region, a second contact portion disposed in the second region, and a conductive path extending in the intermediate region, the flexible printed circuit board is routed in a state where a bent portion is formed in the intermediate region and a folded portion is formed in the second region, the intermediate region includes a first extending portion extending from the bent portion toward the first region and a second extending portion extending from the bent portion toward the second region, and is bent at the bent portion such that a direction of the first extending portion intersects a direction of the second extending portion, an arrangement order of a plurality of the conductive paths in the first extending portion and an arrangement order of a plurality of the conductive paths in the second extending portion are the same in a single rotation direction around the bent portion when the bent portion is viewed in plan view, and the folded portion is folded back such that the second contact portions face a side opposite to the device side.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of a wire harness and a busbar module according to an embodiment;

FIG. 2 is a plan view of the wire harness and the busbar module according to the embodiment;

FIG. 3 is a side view of the wire harness and the busbar module according to the embodiment;

FIG. 4 is a plan view of a flexible printed circuit board according to the embodiment;

FIG. 5 is a cross-sectional view of the flexible printed circuit board according to the embodiment;

FIG. 6 is a plan view of the flexible printed circuit board according to the embodiment;

FIG. 7 is a perspective view of the flexible printed circuit board according to the embodiment;

FIG. 8 is a plan view illustrating a wire harness of a reference example;

FIG. 9 is a plan view of another flexible printed circuit board according to the embodiment;

FIG. 10 is a plan view of the other flexible printed circuit board according to the embodiment;

FIG. 11 is a plan view of another wire harness according to the embodiment; and

FIG. 12 is a plan view of the other wire harness according to the embodiment.

### DETAILED DESCRIPTION OF THE PREFERRED EMBODIMENTS

Hereinafter, a wire harness according to an embodiment of the present invention will be described in detail with reference to the drawings. Note that the present invention is not limited by the embodiment. In addition, constituent elements in the following embodiments include those that can be easily conceived by those skilled in the art or those that are substantially the same as the constituent elements in the following embodiments.

### EMBODIMENTS

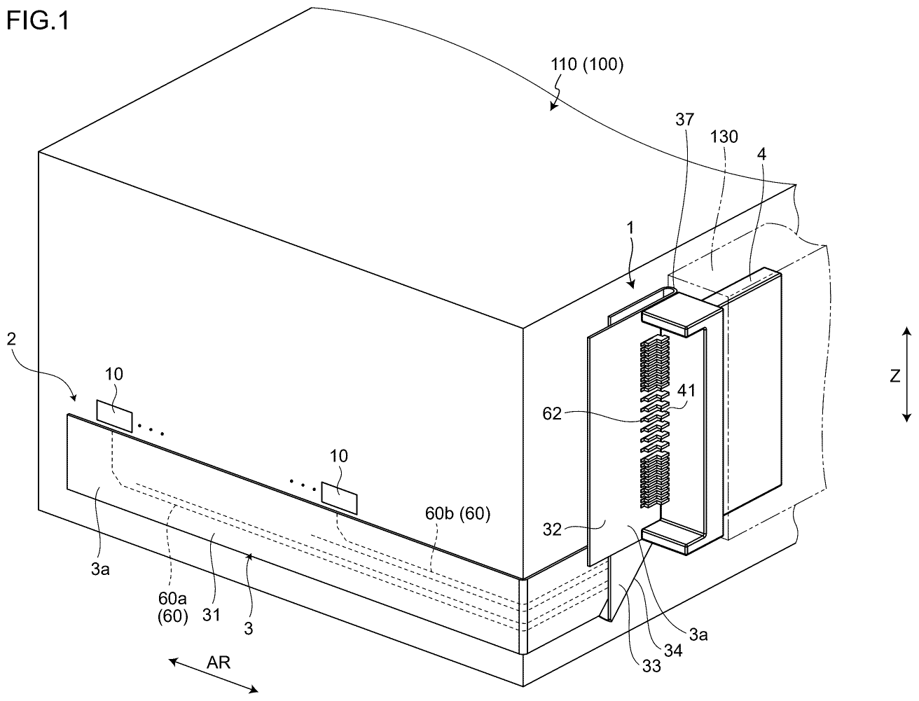

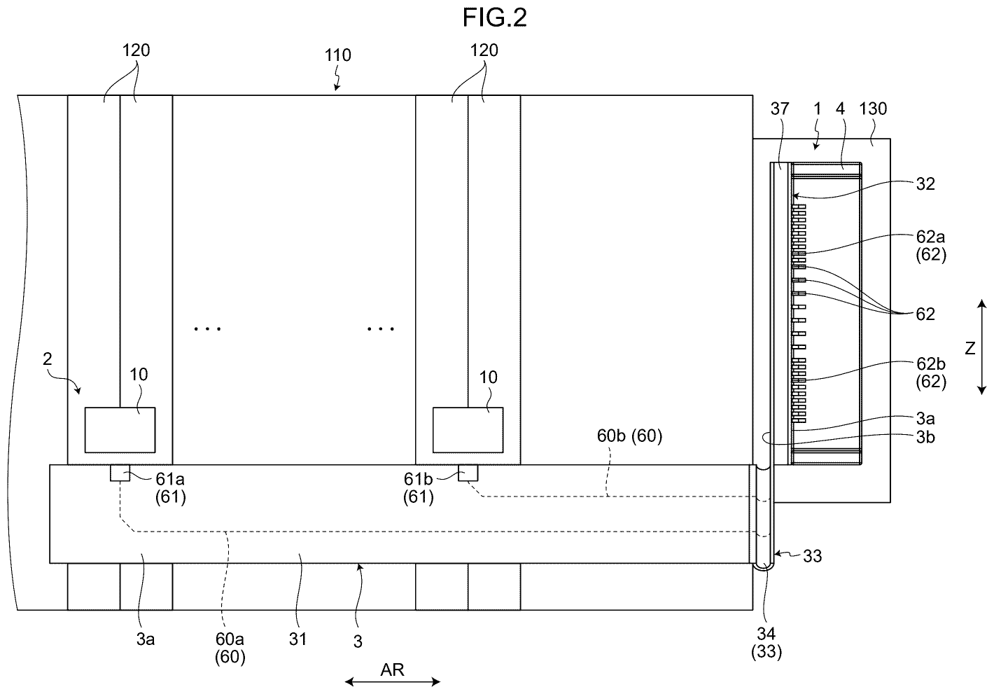

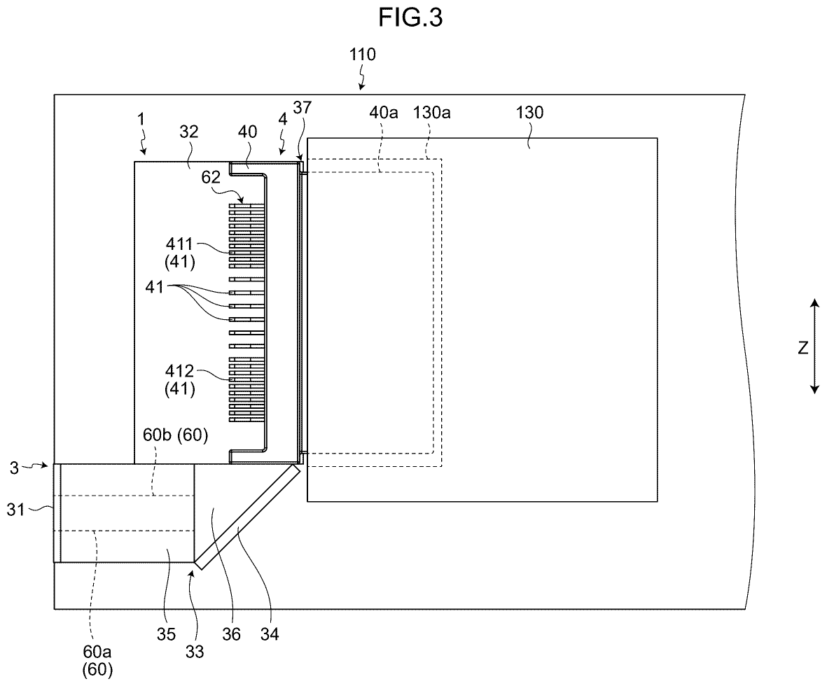

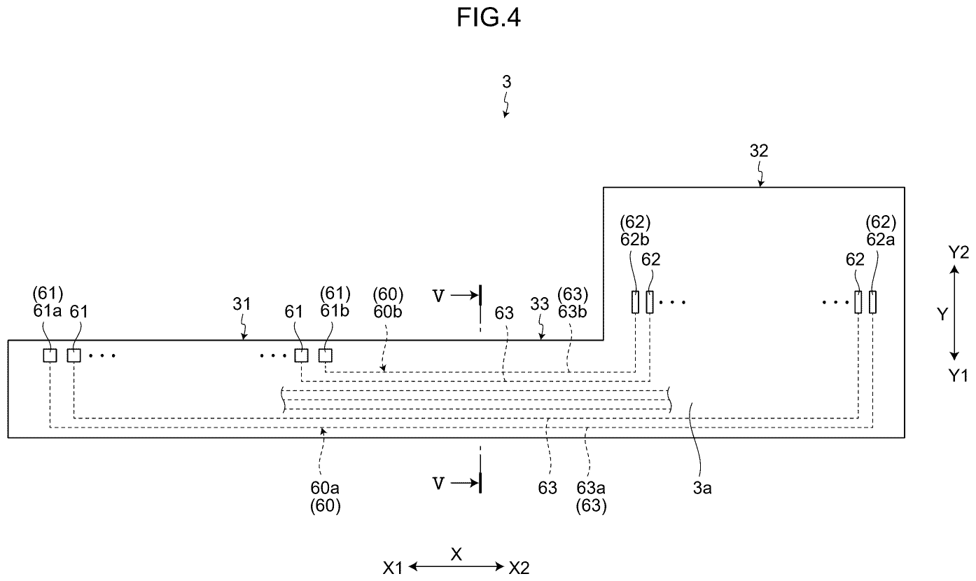

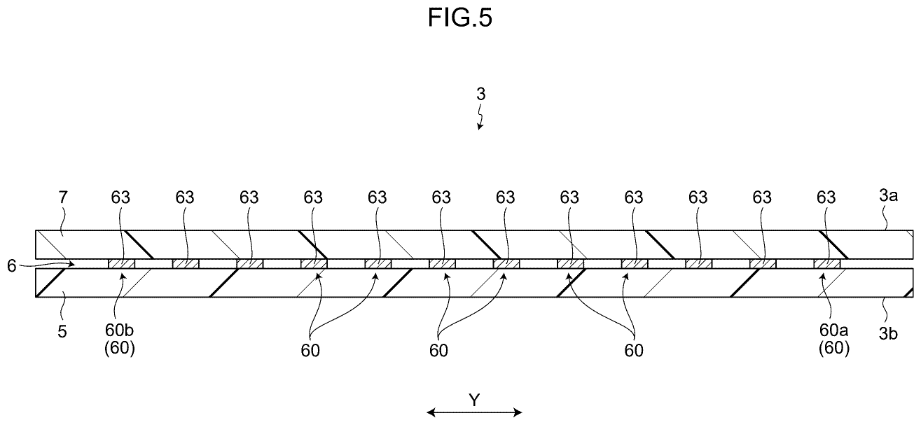

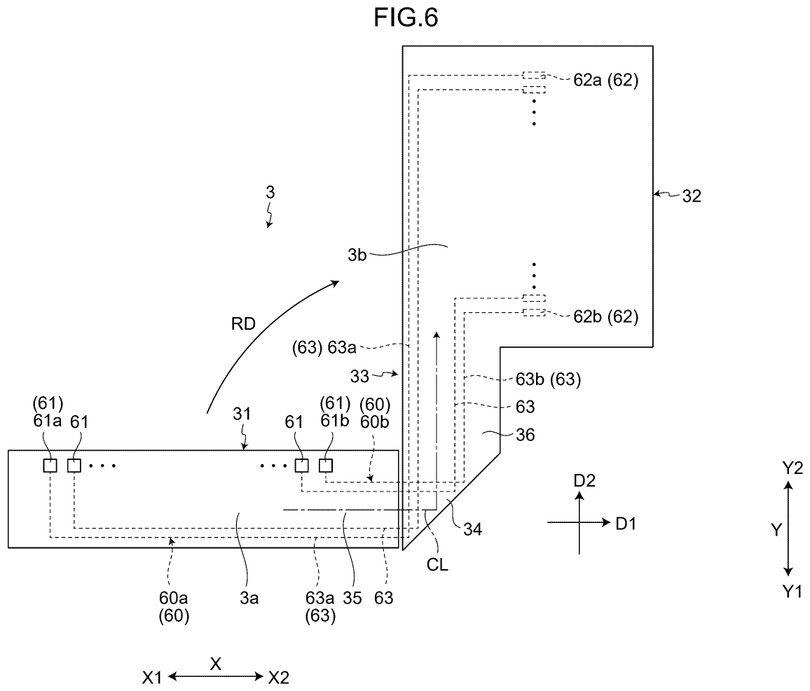

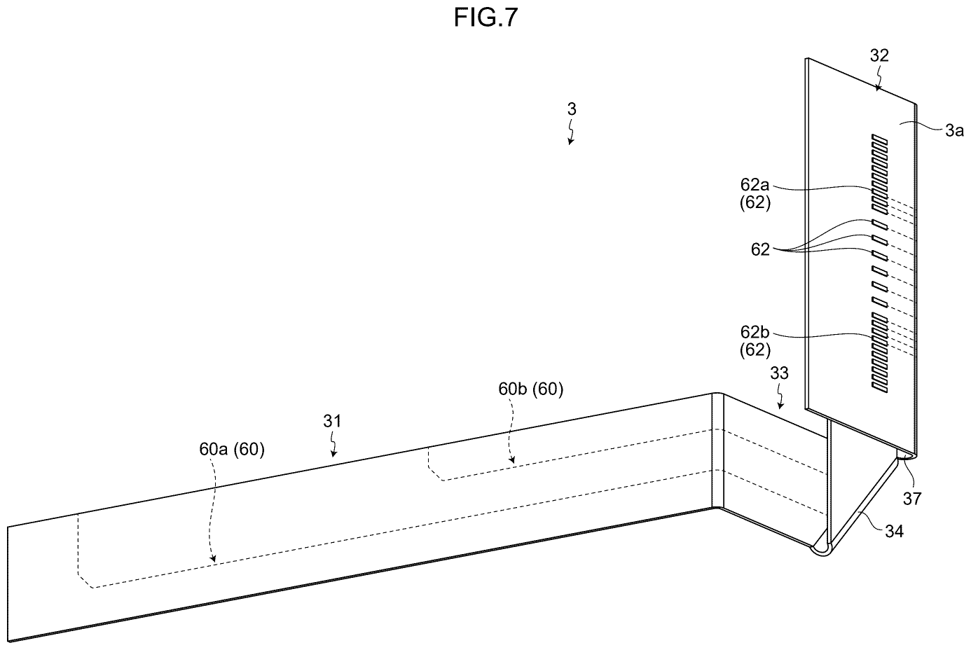

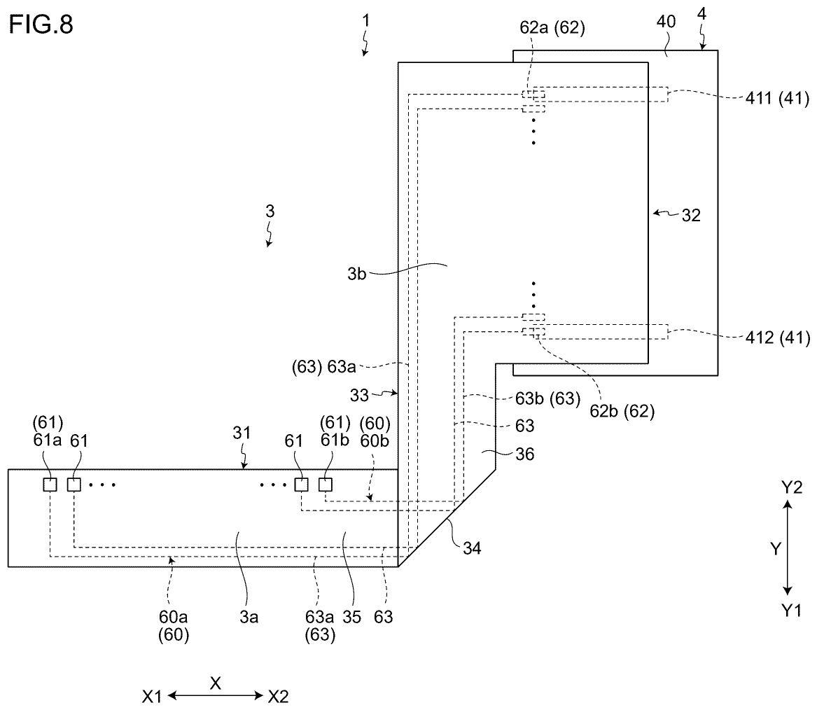

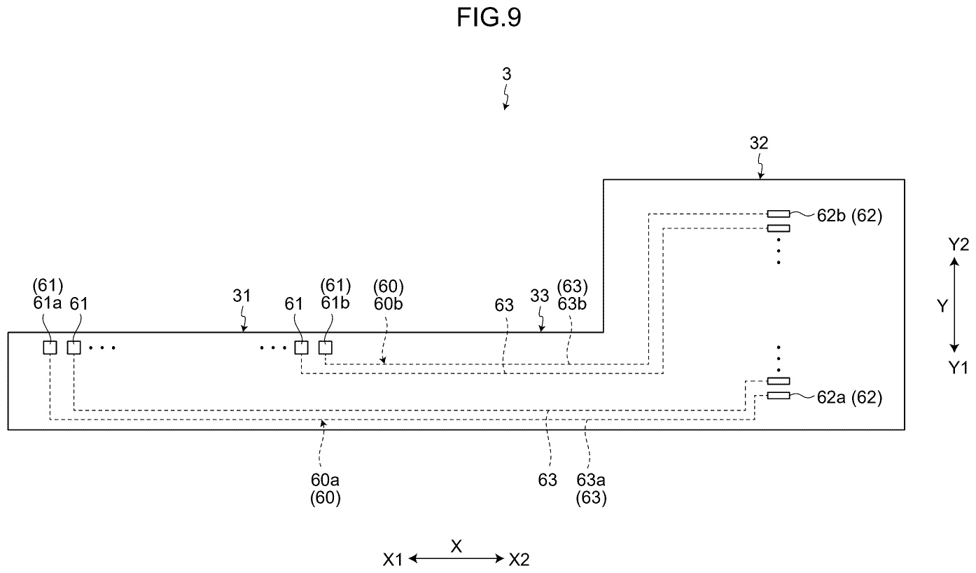

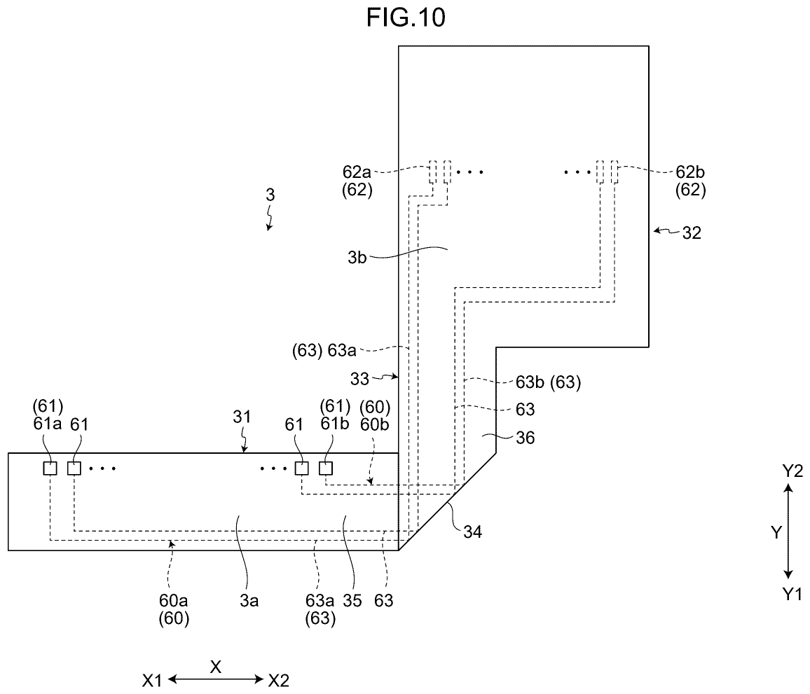

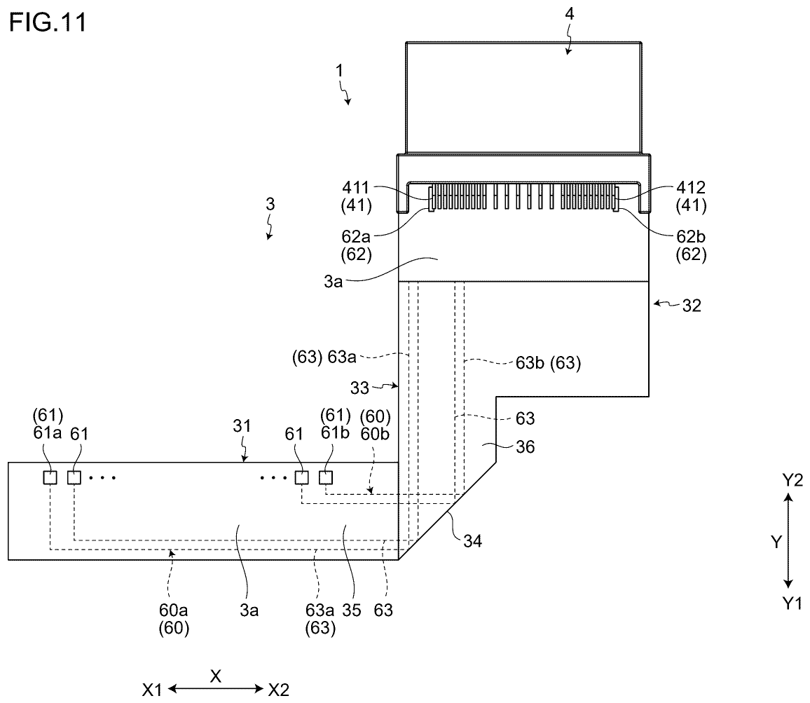

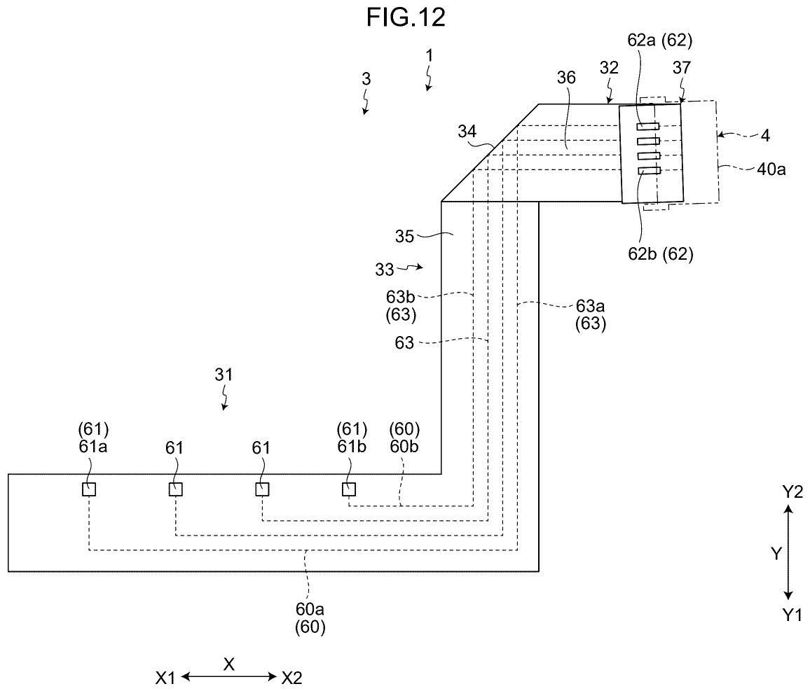

Embodiments will be described with reference to FIGS. 1 to 12. The present embodiment relates to a wire harness. FIG. 1 is a perspective view of the wire harness and a busbar module according to the embodiment, FIG. 2 is a plan view of the wire harness and the busbar module according to the embodiment, FIG. 3 is a side view of the wire harness and the busbar module according to the embodiment, FIG. 4 is a plan view of a flexible printed circuit board according to the embodiment, FIG. 5 is a cross-sectional view of the flexible printed circuit board according to the embodiment, FIG. 6 is a plan view of the flexible printed circuit board according to the embodiment, FIG. 7 is a perspective view of the flexible printed circuit board according to the embodiment, FIG. 8 is a plan view illustrating a wire harness of a reference example, FIGS. 9 and 10 are plan views of another flexible printed circuit board according to the embodiment, and FIGS. 11 and 12 are plan views of another wire harness according to the embodiment. FIG. 5 illustrates a V-V cross section illustrated in FIG. 4.

As illustrated in FIGS. 1 to 3, the wire harness 1 of the present embodiment is disposed, for example, in a battery module 110 of a battery pack 100. The battery pack 100 is mounted as a power source on a vehicle such as an electric vehicle or a hybrid electric vehicle, for example. As illustrated in FIG. 2, the battery module 110 has a plurality of battery cells 120 arranged side by side. In the present specification, a direction in which the plurality of battery cells 120 are arranged is referred to as an arrangement direction AR. A monitoring device 130 is disposed at an end of the battery module 110 in the arrangement direction AR.

The wire harness 1 of the present embodiment includes a flexible printed circuit board 3 and a connector 4. The wire harness 1 is connected to a plurality of busbars 10 to constitute a busbar module 2. The busbars 10 are conductors formed of conductive metal plates, and are fixed to electrodes of the battery cells 120. Each of the busbars 10 connects, for example, two adjacent battery cells 120 in series. The wire harness 1 connects the plurality of busbars 10 to the monitoring device 130 of the battery pack 100. In the wire harness 1, thermistors disposed in the battery cells 120 may be connected to the monitoring device 130. The monitoring device 130 is a device that monitors a state such as a voltage or a temperature of each of the battery cells 120.

The flexible printed circuit board 3 is a flexible flat wiring member, and is configured to be capable of being routed in a bent state. As illustrated in FIG. 5, the flexible printed circuit board 3 of the present embodiment includes a base film 5, a coverlay 7, and a single conductive layer 6. The base film 5 and the coverlay 7 are flexible insulating resin layers. The conductive layer 6 is sandwiched and protected by the base film 5 and the coverlay 7. The conductive layer 6 is, for example, a conductive metal foil, and has a plurality of circuit patterns 60.

As illustrated in FIG. 1, the wire harness 1 of the present embodiment is routed to the battery module 110 in a state where a bent portion 34 and a folded portion 37 are formed in the flexible printed circuit board 3. The bent portion 34 is formed such that the arrangement order of the circuit patterns 60 is reversed between the busbars 10 and the connector 4. The wire harness 1 of the present embodiment includes the single conductive layer 6, but can route the plurality of circuit patterns 60 in a crossed manner. The folded portion 37 is folded back such that contact portions connected to terminals of the connector 4 face the side opposite to the battery module 110 side.

FIG. 4 illustrates the flexible printed circuit board 3 before being bent. The flexible printed circuit board 3 has a longitudinal direction X and a width direction Y. The longitudinal direction X may be a longitudinal direction of a first region 31 to be described later, or may be a direction in which a plurality of first contact portions 61 are arranged. The width direction Y is orthogonal to the longitudinal direction X. In the following description, one side along the longitudinal direction X is referred to as a first side X1, and the other side along the longitudinal direction X is referred to as a second side X2.

The flexible printed circuit board 3 of the present embodiment has a substantially L shape. The flexible printed circuit board 3 has the first region 31, a second region 32, and an intermediate region 33. The shapes of the first region 31, the second region 32, and the intermediate region 33 illustrated are rectangular.

The first region 31 includes an end on the first side X1 of the flexible printed circuit board 3. The second region 32 includes an end on the second side X2 of the flexible printed circuit board 3. The second region 32 is wider than the first region 31 and has a portion protruding in the width direction Y with respect to the first region 31. The intermediate region 33 is a region between the first region 31 and the second region 32, and extends between the first region 31 and the second region 32. The intermediate region 33 illustrated in FIG. 4 extends in the longitudinal direction X from the first region 31 to the second region 32. The width of the intermediate region 33 is equal to the width of the first region 31. That is, the first region 31 and the intermediate region 33 form one rectangular region.

As illustrated in FIG. 5, the flexible printed circuit board 3 has a first surface 3a and a second surface 3b. The first surface 3a is, for example, a surface on the coverlay 7 side. The second surface 3b is, for example, a surface on the base film 5 side. The first contact portions 61 and second contact portions 62, which will be described later, are contact portions exposed to the first surface 3a side.

As illustrated in FIG. 4, each of the circuit patterns 60 includes the first contact portion 61, the second contact portion 62, and a conductive path 63. The first contact portions 61 are contact portions disposed in the first region 31, and are connected to connection objects such as the busbars 10. The connection objects may include the thermistors. The first contact portions 61 are electrically connected to the corresponding connection objects. The first region 31 may have a branch portion extending in the width direction Y. In this case, the first contact portions 61 may be disposed on the branch portion. In the flexible printed circuit board 3 before the bent portion 34 is formed, the plurality of first contact portions 61 are arranged side by side along the longitudinal direction X.

The second contact portions 62 are contact portions disposed in the second region 32, and are connected to terminals 41 of the connector 4. As illustrated in FIG. 4, in the flexible printed circuit board 3 before the bent portion 34 is formed, the plurality of second contact portions 62 are arranged side by side along the longitudinal direction X. The positions of the second contact portions 62 in the width direction Y are, for example, positions protruding in the width direction Y with respect to the first region 31.

Each of the conductive paths 63 is disposed in the intermediate region 33 and connects one of the first contact portions 61 and a corresponding one of the second contact portions 62. In the flexible printed circuit board 3 before the bent portion 34 is formed, the conductive paths 63 extend in the longitudinal direction X in the intermediate region 33. In the intermediate region 33, the plurality of conductive paths 63 are arranged side by side in the width direction Y.

The plurality of conductive paths 63 include a first conductive path 63a and a second conductive path 63b. The first conductive path 63a and the second conductive path 63b are conductive paths 63 disposed at ends in the width direction Y among the plurality of conductive paths 63 connected to the busbars 10. The first conductive path 63a is located at the end on the first side Y1 in the width direction Y among the conductive paths 63 connected to the busbars 10. The second conductive path 63b is located at the end on the second side Y2 in the width direction Y among the plurality of conductive paths 63 connected to the busbars 10. The plurality of conductive paths 63 connected to the busbars 10 extend in a region from the first conductive path 63a to the second conductive path 63b.

In the following description, the circuit pattern 60 having the first conductive path 63a is referred to as a first pattern 60a, and the circuit pattern 60 having the second conductive path 63b is referred to as a second pattern 60b. Among the plurality of first contact portions 61 connected to the busbars 10, the first contact portions 61 of the first pattern 60a and the second pattern 60b are disposed at ends in the longitudinal direction X. That is, among the plurality of first contact portions 61 connected to the busbars 10, a first contact portion 61a of the first pattern is located at an end on the first side X1. Among the plurality of first contact portions 61 connected to the busbars 10, a first contact portion 61b of the second pattern 60b is located at an end on the second side X2. The plurality of circuit patterns 60 may include the circuit pattern 60 connected to an object different from the busbars 10. The first contact portion 61 of this circuit pattern 60 may be disposed between the two first contact portions 61a and 61b, or may be disposed on the first side X1 or the second side X2 with respect to the two first contact portions 61a and 61b.

Among the plurality of second contact portions 62 corresponding to the busbars 10, the second contact portions 62 of the first pattern 60a and the second pattern 60b are disposed at ends in the longitudinal direction X. That is, among the plurality of second contact portions 62 corresponding to the busbars 10, the second contact portion 62a of the first pattern 60a is located at an end on the second side X2. Among the plurality of second contact portions 62 corresponding to the busbars 10, the second contact portion 62b of the second pattern 60b is located at an end on the first side X1. The plurality of circuit patterns 60 may include the circuit pattern 60 connected to an object different from the busbars 10. The second contact portion 62 of this circuit pattern 60 may be disposed between the two second contact portions 62a and 62b, or may be disposed on the first side X1 or the second side X2 with respect to the two second contact portions 62a and 62b.

As illustrated in FIG. 3, the connector 4 includes a housing 40 and the plurality of terminals 41. The housing 40 has a fitting portion 40a fitted to the monitoring device 130. The plurality of terminals 41 are held by the housing 40 and are arranged side by side in the width direction of the housing 40. The plurality of terminals 41 are connected to the corresponding circuit patterns 60. The monitoring device 130 includes a mating connector 130a corresponding to the connector 4. The connector 4 is fitted to the mating connector 130a to connect the plurality of terminals 41 to corresponding terminals of the mating connector 130a.

Here, which terminals 41 the plurality of circuit patterns 60 corresponding to the busbars 10 are connected to are determined based on the configuration of the monitoring device 130. As illustrated in FIG. 3, the plurality of terminals 41 include two terminals 411 and 412 connected to the busbars 10 via the circuit patterns 60. The first terminal 411 is located above the second terminal 412 in the height direction Z of the battery module 110. The plurality of terminals 41 connected to the busbars 10 via the circuit patterns 60 are terminals 41 from the first terminal 411 to the second terminal 412.

As illustrated in FIG. 3, among the plurality of circuit patterns 60 connected to the busbars 10, the first pattern 60a is located below the second pattern 60b in the height direction Z. The circuit patterns 60 connected to the busbars 10 is disposed in a region from the first pattern 60a to the second pattern 60b.

In order to support the configuration of the monitoring device 130, the first pattern 60a may need to be connected to the first terminal 411, and the second pattern 60b may need to be connected to the second terminal 412. In this case, it is necessary to reverse the arrangement order of the circuit patterns 60 in the second region 32 with respect to the arrangement order of the circuit patterns 60 in the first region 31 of the flexible printed circuit board 3. It is conceivable to form the conductive layer 6 of the flexible printed circuit board 3 into multiple layers in order to reverse the arrangement order of the circuit patterns 60, but in this case, manufacturing cost increases.

In the wire harness 1 of the present embodiment, as described below, the arrangement order of the circuit patterns 60 is reversed by forming the bent portion 34 in the flexible printed circuit board 3. As a result, the arrangement order of the circuit patterns 60 can be reversed at low cost.

FIG. 6 illustrates the flexible printed circuit board 3 in which the bent portion 34 is formed. The bent portion 34 is formed in the intermediate region 33 of the flexible printed circuit board 3. That is, the bent portion 34 is formed in a region between the plurality of first contact portions 61 and the plurality of second contact portions 62.

The intermediate region 33 where the bent portion 34 is formed has a first extending portion 35 and a second extending portion 36. The bent portion 34 is formed such that the first surface 3a of the first extending portion 35 and the first surface 3a of the second extending portion 36 face each other. The first extending portion 35 extends from the bent portion 34 toward the first region 31. The second extending portion 36 extends from the bent portion 34 toward the second region 32. The first extending portion 35 extends in a first direction D1, and the second extending portion 36 extends in a second direction D2. The bent portion 34 is formed, for example, such that the first direction D1 and the second direction D2 are orthogonal to each other.

Since the bent portion 34 is formed, the arrangement order of the circuit patterns 60 when the flexible printed circuit board 3 is viewed in plan view is switched. As illustrated in FIG. 6, the intermediate region 33 is bent such that the first conductive path 63a crosses the second conductive path 63b. Thus, the first conductive path 63a crosses the second conductive path 63b in plan view. By forming the bent portion 34, the arrangement order of the circuit patterns 60 when the flexible printed circuit board 3 is viewed in plan view is reversed.

Regarding the arrangement order, FIG. 6 illustrates an intermediate line CL between the first pattern 60a and the second pattern 60b. An arrow of the intermediate line CL indicates a routing direction from the first region 31 toward the second region 32. When the plurality of conductive paths 63 are viewed along the routing direction, the first conductive path 63a is located on the right side with respect to the intermediate line CL and the second conductive path 63b is located on the left side with respect to the intermediate line CL in the first extending portion 35. On the other hand, in the second extending portion 36, the first conductive path 63a is located on the left side with respect to the intermediate line CL, and the second conductive path 63b is located on the right side with respect to the intermediate line CL.

In this manner, in the bent portion 34, the arrangement order of the circuit patterns 60 in plan view can be reserved. Since the arrangement order of the plurality of conductive paths 63 is reversed, the second contact portions 62 are arranged in the second region 32 in a desired order. Among the plurality of second contact portions 62 corresponding to the busbars 10, the second contact portion 62a of the first pattern 60a is located at an end on the second side Y2 in the width direction Y. The second contact portion 62b of the second pattern 60b is located at an end on the first side Y1 in the width direction Y. As a result, the arrangement order of the second contact portions 62 in the second region 32 is such that the first pattern 60a can be connected to the first terminal 411 in FIG. 3 and the second pattern 60b can be connected to the second terminal 412.

When a rotation direction around the bent portion 34 is set as a reference, the arrangement orders of the circuit patterns 60 before and after the bent portion 34 are the same. FIG. 6 illustrates a single rotation direction RD around the bent portion 34. When the arrangement orders in the rotation direction RD are viewed, the arrangement order in the first extending portion 35 and the arrangement order in the second extending portion 36 are the same. In both of the two extending portions 35 and 36, the plurality of conductive paths 63 from the first conductive path 63a to the second conductive path 63b are arranged in the same order along the rotation direction RD.

As illustrated in FIG. 7, the second region 32 is folded back such that the second contact portions 62 face the side opposite to the battery module 110 side. In the second region 32, the folded portion 37 is formed such that a portion of the second region 32 where the second contact portions 62 are provided faces the side opposite to the battery module 110 side. A folding line of the folded portion 37 is along the direction in which the plurality of second contact portions 62 are arranged. The folded portion 37 is formed between the intermediate region 33 and the second contact portions 62. Note that the terminals 41 of the connector 4 may be connected to the second contact portions 62 after the folded portion 37 is formed, or may be connected to the second contact portions 62 before the folded portion 37 is formed.

As illustrated in FIGS. 1 and 3, the connector 4 is connected to the second contact portions 62 so as to face the side opposite to the orientation of the circuit patterns 60. That is, the terminals 41 of the connector 4 are connected to the second contact portions 62 such that the fitting portion 40a is located on the folded portion 37 side with respect to the second contact portions 62. The folded portion 37 is formed in the vicinity of the second contact portions 62. Therefore, the fitting portion 40a protrudes from the folded portion 37 toward the side opposite to the second contact portion 62 side. Accordingly, when the connector 4 is fitted to the mating connector 130a, the second region 32 hardly interferes with the monitoring device 130.

As illustrated in FIGS. 1 and 2, the wire harness 1 has the bent portion 34 and the folded portion 37, and is assembled to the battery module 110 in a state where the busbars 10 are connected. The flexible printed circuit board 3 is assembled to the battery module 110 such that the first surface 3a of the first region 31 faces the side opposite to the battery module 110 side. That is, the flexible printed circuit board 3 is routed in the battery module 110 such that the second surface 3b of the first region 31 faces the battery module 110. The flexible printed circuit board 3 is assembled such that the first region 31 extends along the arrangement direction AR. That is, the flexible printed circuit board 3 is assembled to the battery module 110 such that the plurality of first contact portions 61 are arranged in the arrangement direction AR.

The flexible printed circuit board 3 is routed such that the second region 32 faces a side surface of the battery module 110. The intermediate region 33 is bent along a corner of the battery module 110. The bent portion 34 of the intermediate region 33 is disposed on the side surface of the battery module 110.

The flexible printed circuit board 3 is routed by folding back the second region 32 such that the second contact portions 62 face the side opposite to the battery module 110 side. As illustrated in FIG. 2, in the second region 32, the folded portion 37 is formed such that the portion of the second region 32 where the second contact portions 62 are provided faces the side opposite to the battery module 110. With such a configuration, the second region 32 is accommodated between the connector 4 and the battery module 110.

The busbar module 2 may have a case for holding the flexible printed circuit board 3. In this case, the case may be fixed to the battery module 110. The case may be fixed to the battery module 110 while holding the busbars 10.

The busbars 10 are connected to the connector 4 via the circuit patterns 60. As illustrated in FIG. 2, the arrangement order of the circuit patterns 60 in the first region 31 of the flexible printed circuit board 3 and the arrangement order of the circuit patterns 60 in the second region 32 are switched. According to the wire harness 1 of the present embodiment, the arrangement order of the circuit patterns 60 can be reversed at low cost.

The wire harness 1 may be routed without forming the folded portion 37 in the second region 32. In the wire harness 1 of the reference example illustrated in FIG. 8, the connector 4 is connected to the second region 32 not having the folded portion 37. In this case, the housing 40 of the connector 4 is disposed on the battery module 110 side with respect to the second region 32.

In the flexible printed circuit board 3 before the bent portion 34 is formed, a direction in which the plurality of second contact portions 62 are arranged in the second region 32 is not limited to the longitudinal direction X illustrated in FIG. 4. For example, as illustrated in FIG. 9, the plurality of second contact portions 62 may be arranged in the width direction Y in the second region 32. In this case, among the plurality of second contact portions 62 corresponding to the busbars 10, the second contact portions 62 of the first pattern 60a and the second pattern 60b are disposed at ends in the width direction Y.

Among the plurality of second contact portions 62 corresponding to the busbars 10, the second contact portion 62a of the first pattern 60a is located at an end on the first side Y1. Among the plurality of second contact portions 62 corresponding to the busbars 10, the second contact portion 62b of the second pattern 60b is located at an end on the second side Y2.

FIG. 10 illustrates a state in which the bent portion 34 is formed in the flexible printed circuit board 3 illustrated in FIG. 9. The flexible printed circuit board 3 illustrated in FIGS. 9 and 10 is used, for example, when the connector 4 is fitted to the monitoring device 130 along the height direction Z of the battery module 110. In the second region 32, the folded portion 37 is formed such that the second contact portions 62 face a side opposite to a device such as the battery module 110. The folding line of the folded portion 37 is a line along the direction in which the second contact portions 62 are arranged.

FIG. 11 illustrates a state in which the connector 4 is connected to the flexible printed circuit board 3. In the flexible printed circuit board 3 illustrated in FIG. 11, the folded portion 37 is formed in the second region 32 such that the second contact portions 62 face outward. In other words, the second region 32 is folded back such that the second contact portions 62 face the side opposite to the battery module 110 side.

The plurality of terminals 41 of the connector 4 are connected to the second contact portions 62. The second contact portion 62a of the first pattern 60a is connected to the first terminal 411 of the connector 4, and the second contact portion 62b of the second pattern 60b is connected to the second terminal 412 of the connector 4.

The bent shape of the bent portion 34 is not limited to a shape in which the first extending portion 35 and the second extending portion 36 are orthogonal to each other. For example, the bent portion 34 may be formed such that the second extending portion 36 is inclined with respect to the width direction Y. For example, the bending angle of the bent portion 34 can be adjusted according to the position of the mating connector 130a. By appropriately setting the bending angle of the bent portion 34, it is possible to minimize the total extension of the flexible printed circuit board 3 with respect to the position of the mating connector 130a.

Note that the direction in which the intermediate region 33 extends may be appropriately set according to the position of the mating connector 130a or the like. FIG. 12 illustrates the intermediate region 33 extending in a direction orthogonal to the first region 31. The intermediate region 33 extends from an end of the first region 31 on the second side X2 toward the second side Y2 in the width direction Y. The bent portion 34 is formed in the intermediate region 33. The first extending portion 35 extends in the width direction Y, and the second extending portion 36 extends in the longitudinal direction X. That is, the bent portion 34 is bent such that the second extending portion 36 extends in the longitudinal direction X. The second extending portion 36 extends from the bent portion 34 toward the side opposite to the first region 31 side. By forming the bent portion 34, the arrangement order of the circuit patterns 60 in the second region 32 is reversed with respect to the arrangement order of the circuit patterns 60 in the first region 31. In the second region 32, the folded portion 37 is formed such that the second contact portions 62 face the side opposite to the device side.

As described above, the wire harness 1 of the present embodiment has the plurality of circuit patterns 60 in the single conductive layer 6, and has the flexible printed circuit board 3 routed in a device such as the battery module 110 and the connector 4 having the plurality of terminals 41 connected to the plurality of circuit patterns 60. The flexible printed circuit board 3 includes the first region 31 connected to an object such as the busbars 10, the second region 32 connected to the connector 4, and the intermediate region 33. The intermediate region 33 extends between the first region 31 and the second region 32.

Each of the plurality of circuit patterns 60 includes the first contact portion 61 disposed in the first region 31, the second contact portion 62 disposed in the second region 32, and the conductive path 63 extending in the intermediate region 33. The flexible printed circuit board 3 is routed in a state where the bent portion 34 is formed in the intermediate region 33 and the folded portion 37 is formed in the second region 32. The intermediate region 33 is bent so as to have the first extending portion 35 extending from the bent portion 34 toward the first region 31 and the second extending portion 36 extending from the bent portion 34 toward the second region 32. The intermediate region 33 is bent at the bent portion 34 such that the first direction D1 which is the direction of the first extending portion 35 intersects the second direction D2 which is the direction of the second extending portion 36.

The arrangement order of the plurality of conductive paths 63 in the first extending portion 35 and the arrangement order of the plurality of conductive paths 63 in the second extending portion 36 are the same in the single rotation direction RD around the bent portion 34 when the bent portion 34 is viewed in plan view. The folded portion 37 is folded back such that the second contact portions 62 face the side opposite to the device side. According to the wire harness 1 of the present embodiment, the arrangement order of the plurality of circuit patterns 60 can be switched between the first extending portion 35 and the second extending portion 36. By forming the bent portion 34 and switching the arrangement order of the circuit patterns 60, it is possible to suppress cost as compared with a case where the arrangement order is switched by forming the conductive layer 6 into multiple layers.

In the wire harness 1 of the present embodiment, in the flexible printed circuit board 3 before the bent portion 34 is formed, the plurality of first contact portions 61 are arranged side by side along the longitudinal direction X of the flexible printed circuit board 3 in the first region 31. Therefore, in a configuration in which the plurality of first contact portions 61 are connected to a plurality of objects along the longitudinal direction X, the arrangement order of the circuit patterns 60 can be switched.

The flexible printed circuit board 3 of the present embodiment has the first surface 3a and the second surface 3b opposite to the first surface 3a, and has the first contact portions 61 and the second contact portions 62 exposed on the first surface 3a. The connector 4 is configured to be fitted to a mating connector 130a of a device such as the battery module 110. The flexible printed circuit board 3 is routed such that the second surface 3b of the first region 31 faces a device such as the battery module 110, and the portion of the second region 32 where the second contact portions 62 are provided faces the side opposite to the device side. With such a configuration, the routing can be performed such that the first contact portions 61 and the second contact portions 62 face the side opposite to the device side.

The connector 4 of the present embodiment has the fitting portion 40a to be fitted to the mating connector 130a included in the device. The terminals 41 are connected to the second contact portions 62 such that the fitting portion 40a is located on the folded portion 37 side with respect to the second contact portions 62. With such a configuration, for example, the fitting portion 40a can protrude toward the mating connector 130a.

In the flexible printed circuit board 3 before the bent portion 34 is formed, the plurality of second contact portions 62 may be arranged side by side along the longitudinal direction X of the flexible printed circuit board 3 in the second region 32. In this case, by forming the bent portion 34, the direction in which the second contact portions 62 are arranged can be set to the width direction Y.

The contents disclosed in the above embodiments can be appropriately combined and executed.

In the wire harness according to the present embodiment, a flexible printed circuit board is routed in a state where a bent portion is formed in an intermediate region and a folded portion is formed in a second region. The arrangement order of a plurality of conductive paths in a first extending portion and the arrangement order of the plurality of conductive paths in a second extending portion are the same in a single rotation direction around the bent portion when the bent portion is viewed in plan view. The folded portion is folded back such that second contact portions face a side opposite to the device side. According to the wire harness according to the present embodiment, it is possible to achieve an effect of switching the arrangement order of the circuit patterns while suppressing an increase in cost.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A wire harness comprising:
a flexible printed circuit board having a plurality of circuit patterns in a single conductive layer and routed in a device; and
a connector having a plurality of terminals connected to the plurality of circuit patterns, wherein
the flexible printed circuit board includes a first region connected to an object, a second region connected to the connector, and an intermediate region extending between the first region and the second region,
each of the plurality of circuit patterns includes a first contact portion disposed in the first region, a second contact portion disposed in the second region, and a conductive path extending in the intermediate region,
the flexible printed circuit board is routed in a state where a bent portion is formed in the intermediate region and a folded portion is formed in the second region,
the intermediate region includes a first extending portion extending from the bent portion toward the first region and a second extending portion extending from the bent portion toward the second region, and is bent at the bent portion such that a direction of the first extending portion intersects a direction of the second extending portion,
an arrangement order of a plurality of the conductive paths in the first extending portion and an arrangement order of a plurality of the conductive paths in the second extending portion are the same in a single rotation direction around the bent portion when the bent portion is viewed in plan view, and
the folded portion is folded back such that the second contact portions face a side opposite to the device side.

2. The wire harness according to claim 1, wherein in the flexible printed circuit board before the bent portion is formed, a plurality of the first contact portions are arranged side by side along a longitudinal direction of the flexible printed circuit board in the first region.

3. The wire harness according to claim 1, wherein
the flexible printed circuit board has a first surface and a second surface opposite to the first surface, and has the first contact portions and the second contact portions exposed on the first surface,
the connector is configured to be fitted to a mating connector included in the device, and
the flexible printed circuit board is routed such that the second surface of the first region faces the device and a portion of the second region where the second contact portions are provided faces the side opposite to the device side.

4. The wire harness according to claim 1, wherein
the connector includes a fitting portion to be fitted to a mating connector included in the device, and
the terminals are connected to the second contact portions such that the fitting portion is located on the folded portion side with respect to the second contact portions.

5. The wire harness according to claim 1, wherein in the flexible printed circuit board before the bent portion is formed, a plurality of the second contact portions are arranged side by side along a longitudinal direction of the flexible printed circuit board in the second region.
